(19) United States
(12) Patent Application Publication
(10) Pub. No.: US 2024/0353485 A1
(43) Pub. Date: Oct. 24, 2024

(54) MEASURING ARRANGEMENT FOR EXAMINING A LIGHT-EMITTING DIODE ASSEMBLY AND METHOD

(71) Applicant: ams-OSRAM International GmbH, Regensburg (DE)

(72) Inventor: Stefan Kerscher, Bruck (DE)

(21) Appl. No.: 18/575,780

(22) PCT Filed: Jun. 30, 2022
(86) PCT No.: PCT/EP2022/068086

§ 371 Date: Dec. 29, 2023

(30) Foreign Application Priority Data
Jul. 5, 2021 (DE) 10 2021 117 268.3

(51) Int. Cl. G01R 31/30; G01R 19/165; G01R 31/26; G01R 31/27

(52) U.S. Cl. CPC G01R 31/3008; G01R 19/16566; G01R 31/2635; G01R 31/275

(57) ABSTRACT

In an embodiment a measuring arrangement includes a first supply connection, a second supply connection, at least one signal output, a reference potential connection, a voltage source arranged between the first supply connection and the reference potential connection, a source measuring unit arranged between the second supply connection and the reference potential connection and a controller coupled on an output side to the at least one signal output, wherein the first supply connection, the second supply connection, the at least one signal output and the reference potential connection are configured for connecting to a light-emitting diode assembly.

### CROSS-REFERENCE TO RELATED APPLICATIONS

This patent application is a national phase filing under section 371 of PCT/EP2022/068086, filed Jun. 30, 2022, which claims the priority of German patent application 102021117268.3, filed Jul. 5, 2021, each of which is incorporated herein by reference in its entirety.

### TECHNICAL FIELD

A measuring arrangement for examining a light-emitting diode assembly and a method for examining a light-emitting diode assembly are given.

### BACKGROUND

A light-emitting diode assembly comprises, for example, at least one light-emitting diode (LED) and an integrated circuit with a current control circuit. The current control circuit can be realized as a current sink or current source. The light-emitting diode is arranged in series with the current control circuit. A series circuit, comprising the light-emitting diode and the current control circuit, connects a supply input to a potential connection. The integrated circuit has a circuit supply input and at least one signal connection. Since in the light-emitting diode assembly a terminal of the light-emitting diode is permanently connected to a terminal of the current control circuit in the integrated circuit and these terminals are usually not accessible from the outside, it is difficult to examine a single light-emitting diode.

### SUMMARY

Embodiments provide a measuring arrangement for examining a light-emitting diode assembly and a method for examining a light-emitting diode assembly, with which a leakage current of a light-emitting diode assembly can be detected.

In at least one embodiment, a measuring arrangement for examining a light-emitting diode assembly comprises a first and a second supply connection, at least one signal output, a reference potential connection, a voltage source, a source measuring unit and a controller. The voltage source is arranged between the first supply connection and the reference potential connection. The source measuring unit is arranged between the second supply connection and the reference potential connection. The controller is coupled on the output side to the at least one signal output. The first and second supply connections, the at least one signal output and the reference potential connection are configured for connection to a light-emitting diode assembly.

Advantageously, the voltage source can provide a supply voltage for the light-emitting diode assembly to be tested via the first supply connection. Furthermore, a control signal can be supplied to the light-emitting diode assembly by the control unit via the at least one signal output. A measuring current can be supplied to the light-emitting diode assembly by the source measuring unit via the second supply connection. The source measurement unit picks up a measurement voltage at the second supply connection and digitizes it. This measurement voltage can be evaluated. A very low value of the measurement voltage indicates a high leakage current.

In at least one embodiment of the measuring arrangement, the controller is configured to output a control signal to the at least one signal output, so that a current control circuit of a first number N of current control circuits of the light-emitting diode assembly is activated. The current control circuits of the first number N of current control circuits are realized as current sinks or as current sources. Advantageously, a current control circuit of the first number N of current control circuits can be switched from a n-conducting or a blocking operating state to a conducting operating state by means of the control signal. Thus, a path of the light-emitting diode assembly can be characterized. The first number N is e.g. one. For example, the control signal sets the current control circuit to a high current value, such as the maximum current value. The current control circuit is therefore set to a low resistance. A leakage current of the light-emitting diode can therefore be easily detected.

In one example, the first number N is greater than one. The control signal causes further current control circuits of the first number N of current control circuits to be in the non-conducting or blocking operating state.

In at least one embodiment of the measuring arrangement, the source measuring unit is configured to provide a measuring current at the first supply connection and to measure a measuring voltage that can be tapped between the first supply connection and the reference potential connection. Thus, the measuring current is injected, and the voltage drop generated by the measuring current is measured as the measuring voltage.

In one example, the measuring current is selected so that the at least one light-emitting diode is operated in the forward direction. The measuring current is set so that the expected measuring voltage is less than a lock voltage or threshold voltage of the at least one light-emitting diode. Advantageously, the at least one light-emitting diode is high-impedance in this range. At the same time, the current control circuit is set to low impedance. A possible leakage current flows parallel to the ideal light-emitting diode and flows through the current control circuit. Consequently, a possible leakage current causes a clearly recognizable reduction in the measurement voltage.

In at least one embodiment of the measuring arrangement, the controller is configured to compare the measured voltage with a first reference value and to provide information that the light-emitting diode assembly is not functional if the measured voltage is lower than the first reference value. A low measurement voltage indicates leakage currents or short circuits.

In at least one embodiment of the measuring arrangement, the controller is configured to provide this information at a data output of the measuring arrangement or to store it in a memory of the measuring arrangement.

In at least one embodiment of the measuring arrangement, the controller is configured to compare the measured voltage with a second reference value and to provide the information that the light-emitting diode assembly is not functional if the measured voltage is greater than the second reference value. The first reference value is smaller than the second reference value. A high measurement voltage can indicate a missing connection or another fault. The second reference value is, for example, lower than a lock voltage or threshold voltage of a light-emitting diode.

In one example, the controller is configured to compare the measurement voltage with the first reference value VREF1 and the second reference value VREF2 and to provide information that the light-emitting diode assembly is functional if the measurement voltage VLED is within the following range:

$$VREF 1 \leq VLED \leq VREF 2$$

This means that the measurement voltage is in a range between the first reference value and the second reference value if the light-emitting diode assembly is functional. The measurement voltage is outside this range if the light-emitting diode assembly is not functional.

In various embodiments of the measuring arrangement, the controller is configured,
either to compare the measured voltage with the first reference value and to provide the information that the light-emitting diode assembly is not functional if the measured voltage is lower than the first reference value, or
to compare the measured voltage with the second reference value and to provide the information that the light-emitting diode assembly is not functional if the measured voltage is greater than the second reference value, or
compare the measurement voltage with the first and second reference values and provide information that the light-emitting diode assembly is not functional if the measurement voltage is lower than the first reference value or higher than the second reference value.

In at least one embodiment, the controller is configured to serially output a first number N of different values of the control signal to the at least one signal output, so that the current control circuits of a first number N of current control circuits of the light-emitting diode assembly are serially activated. The first number N is greater than 1. The control signal sets the other current control circuits of the first number N of current control circuits to a non-conducting or a blocking operating state.

In at least one embodiment of the measurement arrangement, the controller is configured to provide the information that the light-emitting diode assembly is not functional if, during the serial output of the first number N of different values of the control signal, at least one measurement voltage of a first number N of measurement voltages is less than a first reference value.

In at least one embodiment of the measuring arrangement, the controller is configured to provide the information that the light-emitting diode assembly is not functional if, during the serial output of the first number N of different values of the control signal, at least one measurement voltage of a first number N of measurement voltages is greater than a second reference value.

In at least one embodiment of the measurement arrangement, the light-emitting diode assembly comprises an integrated circuit and at least one light-emitting diode. The integrated circuit comprises a first number N of current control circuits. A series circuit of a first number N of series circuits each comprises a current control circuit of the first number N of current control circuits and at least one light-emitting diode.

In one example, the first number N is three. A first series circuit of the first number N of series circuits comprises a light-emitting diode emitting in the green spectral range. A second series circuit of the first number N of series circuits comprises a light-emitting diode emitting in the red spectral range. A third series circuit of the first number N of series circuits comprises a light-emitting diode emitting in the blue spectral range.

In at least one embodiment, a method of inspecting a light-emitting diode assembly comprises:
providing a reference potential at a reference potential connection,
providing a supply voltage at a first supply connection via a voltage source,
provision of a control signal at at least one signal output by a control unit,
providing a measuring current at a second supply connection by a source measuring unit, and
tapping and digitizing a measuring voltage at the second supply connection by the source measuring unit.

In at least one embodiment of the method, the controller provides a control signal to the at least one signal output such that a current control circuit of a first number N of current control circuits of the light-emitting diode assembly is activated.

In at least one embodiment of the method, the source measuring unit provides a measuring current at the first supply connection and measures a measuring voltage that can be tapped between the first supply connection and the reference potential connection.

In at least one embodiment of the method, the controller compares the measurement voltage with a first reference value and provides information that the light-emitting diode assembly is not functional if the measurement voltage is less than the first reference value.

In at least one embodiment of the method, the controller compares the measured voltage with a second reference value and provides the information that the light-emitting diode assembly is not functional if the measured voltage is greater than the second reference value.

In one example, the controller provides this information at a data output of the measuring system or stores it in a memory of the measuring system.

In at least one embodiment of the method, the controller serially outputs a first number N of different values of the control signal to the at least one signal output, so that the current control circuits of the first number N of current control circuits of the light-emitting diode assembly are serially activated. The first number N is greater than 1.

In at least one embodiment of the method, the controller provides the information that the light-emitting diode assembly is not functional if, during serial output of the first number N of different values of the control signal, at least one measurement voltage of a first number N of measurement voltages is less than a first reference value.

In one example, each measurement voltage of a first number N of measurement voltages is compared with the same first reference value. In an alternative example, the measured voltages of the first number N of measured voltages are compared with at least two different first reference values, e.g. with a first number N of different first reference values.

In at least one embodiment of the method, the controller provides the information that the light-emitting diode assembly is not functional if, during the serial output of the first number N of different values of the control signal, at least one measurement voltage of a first number N of measurement voltages is greater than a second reference value. The first reference value is smaller than the second reference value.

In one example, each measurement voltage of the first number N of measurement voltages is compared with the same second reference value. In an alternative example, the measurement voltages of the first number N of measurement voltages are compared with at least two different second reference values, e.g. with a first number N of different second reference values. For example, the first and/or the second reference values may be different for light-emitting diodes emitting in different spectral ranges.

In one example, the controller compares the measurement voltage with the first reference value VREF1 and the second reference value VREF2 and provides the information that the light-emitting diode assembly is functional if each measurement voltage VLED of a first number N of measurement voltages is within the following range:

$$VREF 1 \leq VLED \leq VREF 2$$

In at least one embodiment of the method, the reference potential, the supply voltage and the control signal are supplied to an integrated circuit of the light-emitting diode assembly. A current control circuit of a first number of current control circuits of the integrated circuit is activated by the control signal. A series circuit of a first number N of series circuits each comprises a current control circuit of the first number N of current control circuits and at least one light-emitting diode. Furthermore, a series circuit of the first number N of series circuits is connected in each case to the second supply connection and to the reference potential connection.

The measuring arrangement for examining a light-emitting diode assembly is particularly suitable for the method described here for examining a light-emitting diode assembly. The features described in connection with the measuring arrangement for inspecting a light-emitting diode assembly can therefore also be used for the method and vice versa.

In one example, the method for examining a light-emitting diode assembly is implemented as a method for LED characterization in light-emitting diode assemblies, arrangements or products that are operated with an integrated circuit, or IC for short. The LEDs can be realized as intelligent LEDs or RGB LEDs. One application of the light-emitting diode assembly is, for example, ambient lighting or background lighting.

Advantageously, LED assemblies with cracks or gaps in the LED chip are detected and therefore not further processed, in particular not delivered. Advantageously, the method enables an LED leakage current test for light-emitting diode assemblies or products with IC, but without access to individual LEDs.

In one example, the method can be used to carry out an LED low current test, for example as part of an IC heating test, on packaged light-emitting diode assemblies that are operated with an IC and have no direct or indirect access (indirectly, e.g. via the IC) to the individual LEDs. Among other things, a crack in the LED chip can be detected. Cracks in the LED chips can occur, for example, when the LED chips are mounted in a housing and affect the service life of the LEDs.

In one example, a small current, known as leakage, is measured across the LED. For this purpose, a very small current is impressed and the voltage across the component is measured back. Several measurements at different currents then provide information about the condition of the LED chip. This test can be modified depending on the type of LED chip.

This test is preferably carried out via the IC or with the help of the IC, as there is no other access to the LED. The method can be implemented in this way, for example: To carry out this test, the IC is operated and controlled. The IC is put into operation and the internal current sinks, which are used to control the LED, are configured so that at least the required current (also called measuring current) can flow. Now an external current-voltage source is connected for the leakage current measurement. The current/voltage source also carries out this leakage current measurement. If there are several LEDs in one housing, each of which has its own control via an IC, the external switching of the current/voltage sources to the individual LEDs can optionally be omitted.

With the method presented, it is possible, for example, to carry out an LED low current test, e.g. within the feasible limits of an IC heating test, for housings of products operated with an IC that do not have direct or indirect (via the IC) access to the individual LEDs. Consequently, electrical tests of the individual LEDs are possible within the IC limits and a higher quality of the products can be achieved.

In one example, the component or light-emitting diode assembly has two supplies. On the component, the IC supply with a supply voltage is separated from the LED supply with a light-emitting diode supply voltage in order to operate the component or the light-emitting diode assembly externally with one or two current/voltage sources.

In one example, a measuring arrangement comprises an external voltage source that supplies the IC with the supply voltage, an external current source that is connected to the supply input and external electronics that control the IC. Both reference potential connections of the sources are connected to the common reference potential connection of the component or the light-emitting diode assembly.

In one example, the method for examining a light-emitting diode assembly uses the following technical features, given in a possible order of use:
1) The voltage source for the IC supply with the supply voltage is switched on and the IC is initialized.
2) The IC is controlled so that the internal current sink for the required LED is switched on.
3) The current sink in the IC is configured so that at least the current required for this test can flow.
4) A current source is now switched on at the LED supply input and the required measuring current is impressed from this.
5) The measuring voltage between the supply input and a reference potential connection resulting from the measuring current is measured back.
6) Optionally, the measurement described under 4) and 5) can be repeated, depending on the chip type, in order to draw conclusions about the chip condition.

### BRIEF DESCRIPTION OF THE DRAWINGS

Further embodiments and further developments of the measuring arrangement for examining a light-emitting diode assembly or of the method for examining a light-emitting diode assembly result from the embodiment examples explained below in connection with FIGS. 1 to 4. Circuit parts, semiconductor bodies and components which are identical, similar or have the same effect are provided with the same reference signs in the figures.

FIGS. 1 to 3 show embodiments of a light-emitting diode assembly and a measuring arrangement for examining a light-emitting diode assembly; and

FIG. 4 shows an example of a method for examining a light-emitting diode assembly.

### DETAILED DESCRIPTION OF ILLUSTRATIVE EMBODIMENTS

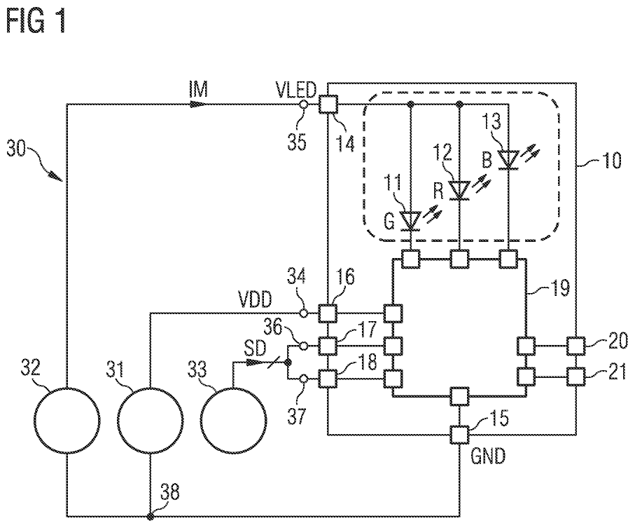

FIG. 1 shows an embodiment example of a light-emitting diode assembly 10 and a measuring arrangement 30 for examining the light-emitting diode assembly 10. The light-emitting diode assembly 10 comprises a number M of light-emitting diodes 11 to 13. In the example shown in FIG. 1, the number M is equal to 3. The number M can also be 1, 2, 4 or greater than four. The light-emitting diodes of the number M of light-emitting diodes 11 to 13 can be different. For example, a first light-emitting diode 11 is realized as a light-emitting diode emitting in the green spectral range, a second light-emitting diode 12 is realized as a light-emitting diode emitting in the red spectral range and a third light-emitting diode 13 is realized as a light-emitting diode emitting in the blue spectral range, abbreviated as LED. The light-emitting diode assembly 10 comprises a supply input 14, a potential connection 15, a circuit supply input 16 and at least one signal connection 17. In the example in FIG. 1, the light-emitting diode assembly 10 comprises the signal connection 17 and a further signal connection 18.

First connections of the number M of light-emitting diodes 11 to 13 are connected to the supply input 14. In FIG. 1, the anodes of the number M of light-emitting diodes 11 to 13 are connected to the supply input 14. The light-emitting diode assembly 10 comprises an integrated circuit 19. Second terminals of the number M of light-emitting diodes 11 to 13 are connected to terminals of the integrated circuit 19. In FIG. 1, cathodes of the number M of light-emitting diodes 11 to 13 are connected to terminals of the integrated circuit 19. The light-emitting diode assembly 10 comprises a first number N of current paths, each of which connects the supply input 14 to the integrated circuit 19. The current paths of the first number N of current paths each have exactly one light-emitting diode. In FIG. 1, the first number N of current paths is thus equal to the number M of light-emitting diodes. The integrated circuit 19 is further connected to the circuit supply input 16, to the at least one signal connection 17, 18 and to the potential connection 15. In the example shown in FIG. 1, the light-emitting diode assembly 10 comprises further signal connections 20, 21, which are connected to the integrated circuit 19. The signal connections 17, 18, 20, 21 are realized, for example, as combined input and output terminals.

The measuring arrangement 30 comprises a voltage source 31, a source measuring unit 32 and a controller 33. Furthermore, the measuring arrangement 30 has a first supply connection 34, a second supply connection 35, at least one signal output 36, 37 and a reference potential connection 38. The voltage source 31 couples the first supply connection 34 to the reference potential connection 38. The source measuring unit 32 couples the second supply connection 35 to the reference potential connection 38. The controller 33 is connected to the at least one signal output 36, 37. The first supply connection 34 is connected to the circuit supply input 16. Correspondingly, the second supply connection 35 is connected to the supply input 14. In addition, the at least one signal output 36, 37 is connected to the at least one signal connection 17, 18. The potential connection 15 is connected to the reference potential connection 38. The connections of the connections or outputs of the measuring arrangement 30 to the connections or inputs of the light-emitting diode assembly 10 are realized in a detachable manner. The connections can, for example, be realized with a test socket. Since, for example, the first supply connection 34 is connected electrically conducting directly to the circuit supply input 16 for carrying out the method, in FIG. 1 a square with the reference sign 16 is connected by a short electrical connection to a circuit provided with the reference sign 34.

The source measuring unit 32 can also be referred to as source and measuring unit, source measure unit, source measurement unit or source meter unit, abbreviated SMU. The source measuring unit 32 is an electronic multifunctional device which is capable of providing a current IM, also referred to as measuring current, at its output and of measuring and digitizing a voltage VLED, referred to as measuring voltage, which can be tapped at the output. Alternatively, for example, the source measuring device 32 can also be configured to provide a voltage VLED at its output and to measure and digitize the current IM flowing through the output. According to the method used here, the source measurement unit 32 provides a measurement current IM. The amount of the measuring current IM can be in a range between 0.1 mA and 100 mA, alternatively in a range between 1 mA and 10 mA.

The voltage source 32 provides a supply voltage VDD. The supply voltage VDD is configured to operate the integrated circuit 19. For example, the supply voltage VDD may be 3.3 V, 5 V or another value. According to the method for examining the light-emitting diode assembly 10, the supply voltage VDD is supplied from the voltage source 31 to the integrated circuit 19.

The controller 33 is realized, for example, as a microcontroller, microprocessor or computer. The controller 33 sends a control signal SD to the integrated circuit 19. The controller 33 activates the integrated circuit 19 by means of the control signal SD. For example, the controller 33 activates the integrated circuit 19 such that a current can flow through the first light-emitting diode 11. The source measuring unit 32 supplies the measuring current IM to the light-emitting diode assembly 10 via the second supply connection 34 and the supply input 14. The source measuring unit 32 measures a measuring voltage VLED between the second supply connection 34 and the reference potential connection 38. The measuring current IM flows through the first light-emitting diode 11, generating the measuring voltage VLED. If the measurement voltage VLED is below a first reference value VREF1, this indicates a leakage current in the area of the first light-emitting diode 11 or a short circuit.

If the measurement voltage VLED has a high value (for example, close to the maximum voltage that can be provided by the source measuring unit 32), this indicates a missing connection in a path that connects the supply input 14 to the potential connection 15 and comprises the first light-emitting diode 11, the integrated circuit 19 and the respective connecting lines. The measurement voltage VLED is thus compared with a second reference value VREF2. The value of the measurement voltage VLED or the result of a comparison of the measurement voltage VLED with the first reference value VREF1 and the second reference value VREF2 are stored, for example.

In a further phase of the method, the control unit 33 outputs the control signal SD with a further value to the integrated circuit 19 so that a current can flow through the second light-emitting diode 12. Analogous to the method described above, the measuring current IM is provided, which flows through the second light-emitting diode 12 and generates a further value of the measuring voltage VLED. The further value of the measurement voltage VLED is digitized and stored. Alternatively, the further value of the measurement voltage VLED is digitized and compared with the first and second reference values VREF1, VREF2. Subsequently, the control unit 33 outputs the control signal SD with a third value to the integrated circuit 19, so that a current flow through the third light-emitting diode 13 is enabled. The measurement voltage VLED is measured and evaluated as described above.

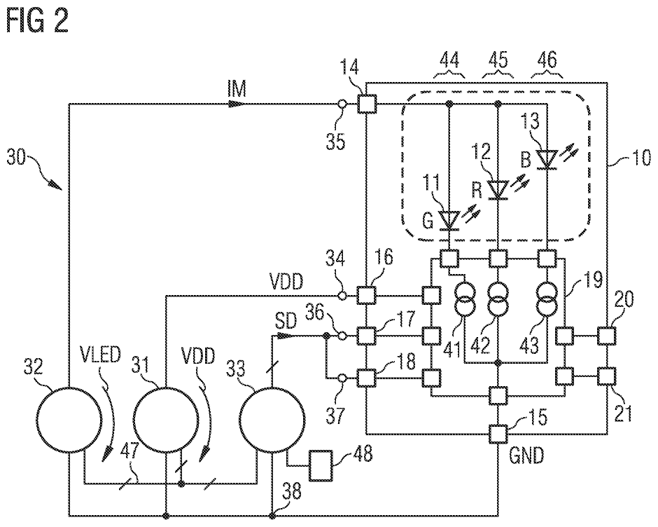

FIG. 2 shows an example of a measuring arrangement 30 and a light-emitting diode assembly 10, which are further embodiments of the embodiments shown in FIG. 1. The integrated circuit 19 comprises a first number N of current control circuits 41 to 43. In FIG. 2, the first number N is equal to 3. However, the first number N may also be 1, 2 or 4. Alternatively, the first number N may be greater than 1, greater than 2 or greater than 3. The current control circuits of the first number N of current control circuits 41 to 43 are realized as current sinks. Thus, the light-emitting diode assembly 10 comprises a first number N of series circuits 44 to 46, each comprising a light-emitting diode 11 to 13 and a current control circuit 41 to 43. A first series circuit 44 thus comprises the first light-emitting diode 11 and a first current control circuit 41. A second series circuit 45 comprises the second light-emitting diode 12 and a second current control circuit 42. A third series circuit 45 comprises the third light-emitting diode 13 and a third current control circuit 43.

The control unit 33 is coupled to the source measuring unit 32 and optionally also to the voltage source 31 via a data line 47 of the measuring arrangement 30. The data line 47 can be realized as a bus line. The control unit 33 controls the source measuring unit 32 and optionally also the voltage source 31. The control unit 33 transmits information about the value of the supply voltage VDD to be set to the voltage source 31. Accordingly, the control unit 33 transmits information about the value of the measuring current IM to be set to the source measuring unit 32. By means of the control signal SD, the controller 33 serially sets the current control circuits of the first number N of current control circuits 41 to 43 to an active operating state, i.e. to a conductive operating state. The control signal SD sets in each case one current control circuit of the first number N of current control circuits 41 to 43 to an active or conducting operating state and the other current control circuits of the first number N of current control circuits 41 to 43 to a non-active, n-conducting or blocking operating state. The current control circuits of the first number N of current control circuits 41 to 43 are operated in a pulse-width modulated manner, for example. The control signal SD sets, for example, a duty cycle of the current control circuit that has the active operating state to a value greater than 0, e.g. 50% or 100%, and the duty cycles of the other current control circuits of the first number N of current control circuits 41 to 43 that have the non-active, non-conducting or blocking operating state to the value 0.

The source measuring unit 32 provides the value of the measuring voltage VLED for the control unit 33 via the data line 47. The control unit 33 is coupled to a memory 48 of the measuring arrangement 30. The control unit 33 stores the values of the measurement voltage VLED or the results of the comparison of the measurement voltage VLED with the first and/or second reference value VREF1, VREF2 in the memory 48.

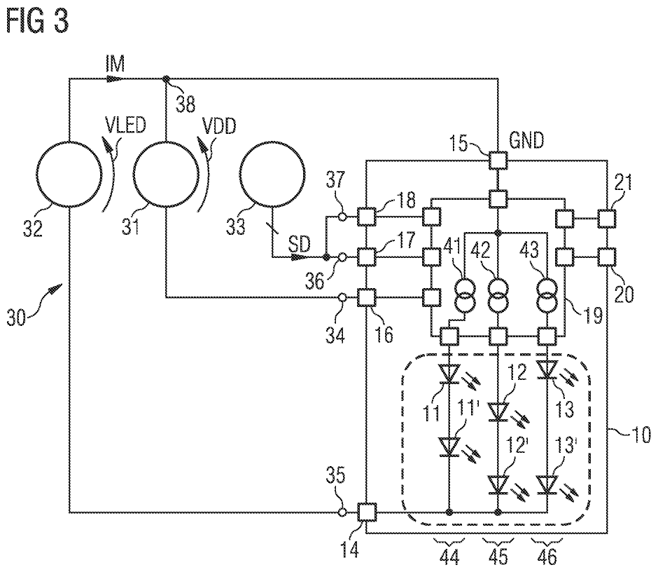

In an alternative embodiment, not shown, at least one series circuit of the first number N of series circuits 44 to 46 comprises at least one further light-emitting diode (as shown in FIG. 3). The series circuits may have the same number or different numbers of light-emitting diodes.

FIG. 3 shows an example of a measuring arrangement 30 and a light-emitting diode assembly 10, which is a further development of the embodiments shown in FIGS. 1 and 2. The current control circuits of the first number N of current control circuits 41 to 43 are realized as current sources. In FIG. 3, cathodes of the first number N of light-emitting diodes 11 to 13 are connected to the supply input 14. Anodes of the first number N of light-emitting diodes 11 to 13 are connected to terminals of the integrated circuit 19. As shown in FIG. 3, a series circuit of the first number N of series circuits 44 to 46 may also have more than one light-emitting diode 11, 11′, 12, 12′, 13, 13′. The supply voltage VDD is negative. For example, the supply voltage VDD can be −3.3 V, −5 V or another value. The measuring voltage VLED and the measuring current IM also have negative values. The method for examining the light-emitting diode assembly 10 can be carried out as described in FIGS. 1 and 2.

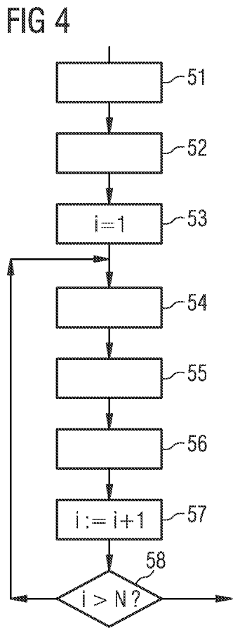

FIG. 4 shows an example of a method for examining a light-emitting diode assembly 10, which is a further development of the embodiments shown above. According to a first block 51, a reference potential GND is provided from the reference potential connection 38 of the measuring arrangement 30 to the potential connection 15 of the light-emitting diode assembly 10. In a second block 52, a supply voltage VDD is provided from the voltage source 31 of the integrated circuit 19 via the first supply connection 34 of the measuring arrangement 30 and the circuit supply input 16 of the light-emitting diode assembly 10.

The measurement is described in the following steps: Since the light-emitting diode assembly comprises the first number N of series circuits 44 to 46 or the first number N of current control circuits 41 to 43, a first number N of measurements are performed. An index i thus runs from the value 1 to the value N. In a third block 53, the index i is set to the value 1. The following blocks 54 to 58 are thus run through N times. In a fourth block 54, the controller 33 activates an i-th current control circuit of the first number N of current control circuits 41 to 43 by means of an i-th value of the control signal SD. Furthermore, in a fifth block 55, the source measuring unit 32 provides the measuring current IM at the second supply connection 35 of the measuring arrangement 30 to the supply input 14 of the light-emitting diode assembly 10 and measures and digitizes an i-th value of the measuring voltage VLED. The i-th value of the measured voltage VLED is transmitted from the source measuring unit 32 to the control unit 33 via the data line 47.

In a sixth block 56, the control unit 33 compares the i-th measured value with at least one reference value. For example, the control unit 33 compares the i-th measured value of the measured voltage VLED with the first reference value VREF1. If the i-th measured value of the measured voltage VLED is below the first reference value VREF1, the control unit 33 generates the information that the i-th series circuit 44 to 46 is defective. For example, the leakage current of the i-th series circuit is too high.

Alternatively, the control unit 33 compares the i-th measured value of the measured voltage VLED with the first and second reference values VREF1, VREF2. If the i-th measured value is between the first reference value VREF1 and the second reference value VREF2, the control unit 33 generates the information that the i-th series circuit is functional. If the i-th measured value of the measured voltage VLED is above the second reference value VREF2, the control unit 33 generates the information that the i-th series circuit is not functional (for example, a connection is interrupted). The control unit 33 stores the information that the i-th series circuit is functional or non-functional in the memory 48, for example. Alternatively, the control unit 33 provides this information at a data output of the measuring arrangement 30.

In a seventh block 57, the index i is increased by 1. In a query block 58, the index i is compared with the first number N. If the index i is greater than N, the measurement and evaluation are completed. If the index i is less than or equal to N, the loop continues, starting with the fourth block 54. A block can also be referred to as a module or software block or process step. Typically, a block comprises several process steps.

In an alternative embodiment, not shown, the source measuring unit 32 serially outputs the measuring current IM with at least two different values. Thus, each series circuit of the first number N of series circuits 44 to 46 is tested with at least two values of the measuring current IM.

In an alternative embodiment not shown, the source measurement unit 32 provides the measurement voltage VLED and measures and digitizes the measurement current IM. A value of the measurement voltage VLED is less than a value of a lock voltage or threshold voltage of the at least one light-emitting diode of a series circuit. If the measuring current IM is greater than a first reference value, the light-emitting diode assembly 10 is not functional (cause e.g. excessive leakage current). If the measuring current IM is less than a second reference value, the light-emitting diode assembly 10 is not functional (cause e.g. an interruption).

The invention is not limited to the embodiments of the invention by the description thereof. Rather, the invention includes any new feature as well as any combination of features, which includes in particular any combination of features in the claims, even if this feature or combination itself is not explicitly stated in the claims or embodiments.

1.-16. (canceled)

17. A measuring arrangement comprising:
a first supply connection;
a second supply connection;
at least one signal output;
a reference potential connection;
a voltage source arranged between the first supply connection and the reference potential connection;
a source measuring unit arranged between the second supply connection and the reference potential connection; and
a controller coupled on an output side to the at least one signal output,
wherein the first supply connection, the second supply connection, the at least one signal output and the reference potential connection are configured for connecting to a light-emitting diode assembly.

18. The measuring arrangement according to claim 17, wherein the controller is configured to output a control signal to the at least one signal output so that a current control circuit of a first number N of current control circuits of the light-emitting diode assembly is activated.

19. The measuring arrangement according to claim 17, wherein the source measuring unit is configured to provide a measuring current at the second supply connection and to measure a measuring voltage that is tappable between the second supply connection and the reference potential connection.

20. The measuring arrangement according to claim 19, wherein the controller is configured to compare the measurement voltage with a first reference value and to provide information that the light-emitting diode assembly is not functional in response to the measurement voltage being less than the first reference value.

21. The measuring arrangement according to claim 20, wherein the controller is configured to compare the measurement voltage with a second reference value and to provide information that the light-emitting diode assembly is not functional in response to the measurement voltage being is greater than the second reference value.

22. The measuring arrangement according to claim 17,
wherein the controller is configured to serially output a first number N of different values of a control signal to the at least one signal output so that current control circuits of a first number N of current control circuits of the light-emitting diode assembly are serially activated, and
wherein the first number N is greater than 1.

23. The measuring arrangement according to claim 22, wherein the controller is configured to provide information that the light-emitting diode assembly is not functional, during the serial output of the first number N of different values of the control signal, in response to at least one measurement voltage of a first number N of measurement voltages being less than a first reference value.

24. The measuring arrangement according to claim 22, wherein the controller is configured to provide information that the light-emitting diode assembly is not functional, during the serial output of the first number N of different values of the control signal, in response to at least one measurement voltage of a first number N of measurement voltages being greater than a second reference value.

25. The measuring arrangement according to claim 17,
wherein the light-emitting diode assembly comprises an integrated circuit and a number of light-emitting diodes,
wherein the integrated circuit comprises a first number N of current control circuits, and
wherein a series circuit of a first number N of series circuits comprises a current control circuit of the first number N of current control circuits and a light-emitting diode of the number 0 light-emitting diodes.

26. A method for inspecting a light-emitting diode assembly, the method comprising:
providing a reference potential at a reference potential connection;
providing a supply voltage at a first supply connection by a voltage source;
providing, by a controller, a control signal at at least one signal output;
providing, by a source measuring unit, a measuring current at a second supply connection; and
tapping and digitizing, by the source measuring unit, a measuring voltage at the second supply connection.

27. The method according to claim 26, further comprising, emitting, by the controller, the control signal to the at least one signal output so that a current control circuit of a first number N of current control circuits of the light-emitting diode assembly is activated.

28. The method according to claim 26, further comprising:
providing, by the source measuring unit, a measuring current at the second supply connection; and
measuring a measuring voltage that is tappable between the second supply connection and the reference potential connection.

29. The method according to claim 28, further comprising:
comparing, by the controller, the measurement voltage with a first reference value; and
providing information that the light-emitting diode assembly is not functional in response to the measurement voltage being less than the first reference value.

30. The method according to claim 29, further comprising:
comparing, by the controller, the measurement voltage with a second reference value; and
providing information that the light-emitting diode assembly is not functional in response to the measurement voltage being greater than the second reference value.

31. The method according to claim 26,
wherein the controller serially outputs a first number N of different values of the control signal to the at least one signal output so that current control circuits of a first number N of current control circuits of the light-emitting diode assembly are serially activated, and
wherein the first number N is greater than 1.

32. The method according to claim 26,
wherein the reference potential, the supply voltage and the control signal are fed to an integrated circuit of the light-emitting diode assembly,
wherein a current control circuit of a first number N of current control circuits of the integrated circuit is activated by the control signal,
wherein a series circuit of a first number N of series circuits comprises a current control circuit of the first number N of current control circuits and at least one light-emitting diode of a number of light-emitting diodes, and
wherein a series circuit of the first number N of series circuits is connected in each case to the second supply connection and to the reference potential connection.

33. A measuring arrangement comprising:
a first supply connection;
a second supply connection;
at least one signal output;
a reference potential connection;
a voltage source arranged between the first supply connection and the reference potential connection;
a source measuring unit arranged between the second supply connection and the reference potential connection; and
a controller coupled on an output side to the at least one signal output,
wherein the first supply connection, the second supply connection, the at least one signal output and the reference potential connection are configured for connecting to a light-emitting diode assembly,
wherein the controller is configured to serially output a first number N of different values of a control signal to the at least one signal output so that current control circuits of a first number N of current control circuits of the light-emitting diode assembly are serially activated, and
wherein the first number N is greater than 1.
